(19) United States
(12) Patent Application Publication
(10) Pub. No.: US 2019/0190268 A1
(43) Pub. Date: Jun. 20, 2019

(54) POWER SUPPLY MONITORING DATA PROCESSING DEVICE, POWER SUPPLY MONITORING DATA PROCESSING METHOD, AND POWER SUPPLY MONITORING DATA PROCESSING PROGRAM

(71) Applicant: Panasonic Intellectual Property Management Co., Ltd., Osaka (JP)

(72) Inventor: JUN HIRANO, Osaka (JP)

(21) Appl. No.: 16/326,083

(22) PCT Filed: Jun. 1, 2018
(86) PCT No.: PCT/JP2018/021121

§ 371 Date: Feb. 15, 2019

(30) Foreign Application Priority Data
Jul. 26, 2017 (JP) 2017-144503

(51) Int. Cl. H02J 3/28; H02J 13/00; H02J 9/06; G01R 31/42

(52) U.S. Cl. CPC H02J 3/28; G01R 31/42; H02J 9/061; H02J 13/0013

(57) ABSTRACT

A data acquisition section acquires first data and second data as monitoring data of a power source system that includes a switching section that selectively outputs AC power supplied from a system power source or an internal combustion power generation device, an AC/DC converter that converts the AC power output from the switching section into DC power and outputs the DC power, and a power storage device connected to a DC bus. The first data contains an output voltage and/or an output current of the switching section; the second data contains an output voltage and/or an output current of the power source system. The data processor estimates an operational state of the internal combustion power generation device, based on the first data and the second data, and generates a modification plan for a system configuration and/or a discharge lower limit of the power storage device to shorten an operational time of the internal combustion power generation device.

### TECHNICAL FIELD

The present invention relates to a power source monitoring data processing device, a power source monitoring data processing method, and a power source monitoring data processing program, all of which are intended to process monitoring data of a power source system equipped with a backup power storage device.

### BACKGROUND ART

Electric power conditions in developing countries, including India, Southeast Asian courtiers, and African courtiers, are worse than those in developed countries, including Japan and European countries. Therefore, electric power is often cut off. Power failures in such developing countries happen usually accidentally but sometimes in a planned way. Thus, as a rule, infrastructure installations, such as cellular phone base stations, need to have backup power source systems, which are used upon power failures in system power sources. To provide quality communication services for developing countries, stable facility control for communication facilities and secured power sources are an important key.

In many cases, hybrid systems in which a power generation device and a storage battery collaborate with each other are used as backup power source systems. This power generation device can be a solar or wind power generation device. However, the power generation device is usually an internal combustion power generation device (for example, a diesel generator or a gas turbine generator) that can generate electric power independently of weather (for example, see PTLs 1 and 2). If an internal combustion power generation device is used, fossil fuel is needed.

### CITATION LIST

### Patent Literature

PTL 1: Unexamined Japanese Patent Publication No. 2004-062254

PTL 2: Unexamined Japanese Patent Publication No. 2016-039648

### SUMMARY OF THE INVENTION

When a power failure occurs in a system power source, a backup power source system causes both a storage battery and an internal combustion power generation device to supply a backup power source to a load. In this case, if the power source is not controlled in accordance with stability of the system power source, the internal combustion power generation device may inevitably operate for an unexpectedly long time. As a result, excessive amounts of fuel might be consumed. Many backup power source systems used in developing countries may fail to permit checking of present settings and environment, thus making verification of a fuel consumption difficult.

The present invention deals with the above situation with an object of providing a technique for continuously and efficiently operating a power source system in which a power storage device and an internal combustion power generation device collaborate with each other.

According to an aspect of the present invention which achieves the above object, a power source monitoring data processing device includes: a data acquisition section that acquires first data and second data as monitoring data of a power source system, the power source system including a switching section that selectively outputs alternating current (AC) power supplied from a system power source or an internal combustion power generation device, an alternating current/direct current (AC/DC) converter that converts the AC power output from the switching section into direct current (DC) power and outputs the DC power to a DC load, and a power storage device connected to a DC bus between the AC/DC converter and the DC load, the first data containing an output voltage and/or an output current of the switching section, the second data containing an output voltage and/or an output current of the power source system; and a data processor that estimates an operational state of the internal combustion power generation device, based on the first data and the second data acquired by the data acquisition section and that generates a modification plan for a system configuration and/or a discharge lower limit of the power storage device to shorten an operational time of the internal combustion power generation device.

Any desired combinations of the above-described components and converted expressions of the present invention in methods, devices, systems, and other similar entities are still effective as aspects of the present invention.

The present invention achieves a continuous and efficient operation of a power source system in which a power storage device and an internal combustion power generation device collaborate with each other.

### BRIEF DESCRIPTION OF DRAWINGS

FIG. 1 is a block diagram of an overall configuration of communication facilities, a central monitoring system, and a power source monitoring data processing device.

FIG. 2 illustrates an example of a configuration of a power source system in a communication facility.

FIG. 3 illustrates an example of a time transition of a state of a power source in a certain power source system.

FIG. 4 illustrates an example of a configuration of the power source monitoring data processing device according to an exemplary embodiment of the present invention.

FIG. 5 is a flowchart of an example of an operation of the power source monitoring data processing device according to the exemplary embodiment of the present invention.

FIG. 6 illustrates an example of a format of a fuel reduction performance evaluation report.

FIGS. 7 (a) and (b) each illustrate a modification of a graph area in which an operation result and an estimated operation performed before improvement are shown in FIG. 6.

### DESCRIPTION OF EMBODIMENT

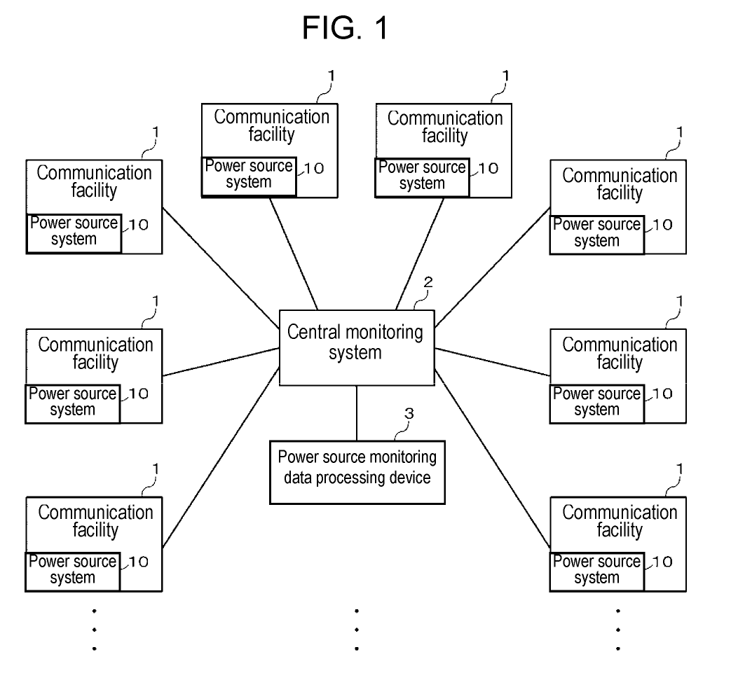

FIG. 1 illustrates a block diagram of an overall configuration of communication facilities 1, central monitoring system 2, and power source monitoring data processing device 3. Each communication facility 1 has power source system 10. The following description gives an example in which each communication facility 1 serves as a base station device for cellular phones.

Base station devices for cellular phones installed at many more sites provide higher communication quality. In some vast nations, base station devices are installed at 100,000 or more sites.

Central monitoring system 2 is a system that remotely monitors power source systems 10 in the plurality of communication facilities 1. For example, central monitoring system 2 may include a plurality of servers. Central monitoring system 2 is connected to power source systems 10 in communication facilities 1 over a network and collects monitoring data from power source systems 10. The network may be the Internet or any dedicated line.

Power source monitoring data processing device 3 is a device that processes the monitoring data of the plurality of power source systems 10 collected by central monitoring system 2. For example, power source monitoring data processing device 3 may include an information processing device, such as a server, a personal computer (PC), a tablet, or a smartphone. Power source monitoring data processing device 3 acquires the monitoring data of the plurality of power source systems 10 from central monitoring system 2 over the network. Alternatively, power source monitoring data processing device 3 acquires the monitoring data of the plurality of power source systems 10 via a recording medium. FIG. 1 illustrates the configuration in which power source monitoring data processing device 3 is separated from central monitoring system 2; however, a configuration in which power source monitoring data processing device 3 is incorporated in central monitoring system 2 may be possible. FIG. 1 illustrates the (star type) configuration in which the plurality of power source systems 10 are individually connected to central monitoring system 2; however, a different connection configuration, such as a (tree type) hierarchic structure according to a geographic situation or a (loop type) multiplexing intended for stable communication, or a combination of some of these configurations may be possible.

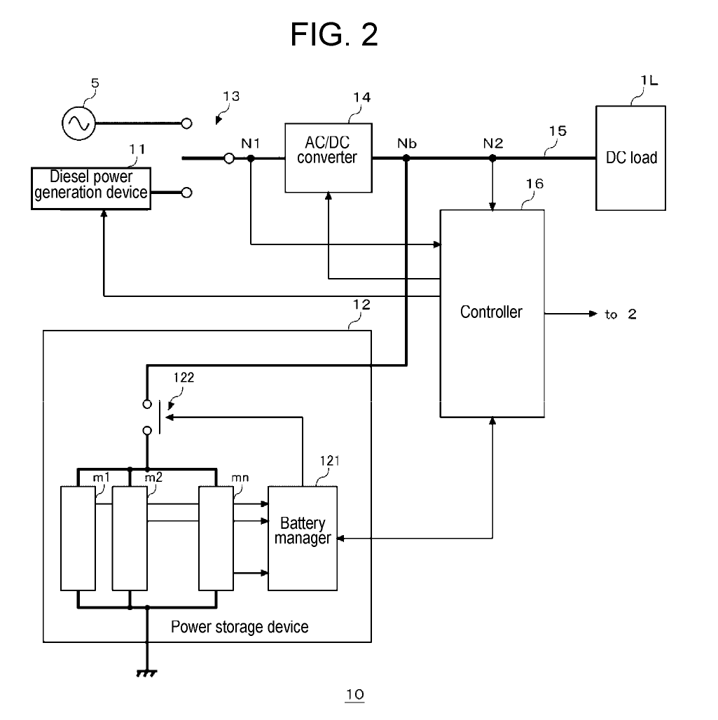

FIG. 2 illustrates an example of a configuration of power source system 10 in communication facility 1. Power source system 10 in FIG. 2 includes three power sources: system power source 5, diesel power generation device 11, and power storage device 12. Diesel power generation device 11 is a device that generates electric power with a compression ignition scheme by using gas oil as a main fuel and outputs alternating current (AC) power. Instead of diesel power generation device 11, a gas turbine generator may be used. In this case, the main fuel is natural gas. In some cases, power source system 10 is connected to another power source facility such as a solar photovoltaic system, which is not illustrated in this exemplary embodiment.

Switching section 13 selectively outputs AC power supplied from system power source 5 and AC power supplied from diesel power generation device 11. AC/DC converter 14 converts the AC power supplied via switching section 13 into direct current (DC) power having a predetermined voltage (referred to below as a reference voltage) and outputs the DC power to DC bus 15. DC bus 15 is connected to DC load 1L in communication facility 1. For example, DC bus 15 may be a busbar.

DC bus 15 is connected to power storage device 12, which charges DC bus 15 with the DC power or discharges the DC power from DC bus 15. This charging or discharging operation is usually controlled based on a state (for example, a voltage or current value) on DC bus 15.

Power storage device 12 includes: a plurality of power storage modules m1 to mn interconnected in parallel; battery manager 121; and switch 122. Each of power storage modules m1 to mn includes a plurality of cells connected in series. Each cell may be a lithium ion battery cell, a nickel hydride battery cell, a lead battery, an electric double layer capacitor cell, or a lithium ion capacitor cell, for example. The following description gives an example in which a lithium ion battery cell (nominal voltage: 3.6 V to 3.7 V) is used. Power storage modules m1 to mn interconnected in parallel are connected to DC bus 15 via switch 122. For example, switch 122 may be a relay.

Battery manager 121 monitors states of the plurality of power storage modules m1 to mn. More specifically, battery manager 121 monitors voltages, currents, and temperatures of the cells included in the plurality of power storage modules m1 to mn. Battery manager 121 controls state-of-charge (SOC), state-of-health (SOH), and equalization, and protects the batteries.

The SOC can be estimated by a current integration method or an open circuit voltage (OCV) method. The SOH is specified by a ratio of present full charge capacity to initial full charge capacity. This value decreases (approaches zero) as degradation increases. The SOH can be estimated based on a correlation with an internal resistance. The internal resistance can be estimated by dividing a voltage drop occurring when a predetermined current flows through a cell for a given time by the current. The internal resistance has the following relationship: the internal resistance decreases as the temperature rises and increases as the battery degrades.

The equalization control refers to control under which a voltage across or a capacity of a plurality of cells interconnected in series is equalized. The battery protection refers to control under which, when an overvoltage, excessively low voltage, overcurrent, or temperature abnormality is detected, switch 122 is turned off to electrically disconnect the plurality of power storage modules m1 to mn from DC bus 15.

Controller 16 monitors and controls overall power source system 10. Controller 16 detects first data and second data as basic monitoring data of power source system 10. The first data refers to a voltage value and/or current value at first point (N1); the second data refers to a voltage value and/or current value at second point (N2). First data is a three-phase or single-phase AC voltage or current value output from switching section 13. Second data is a DC voltage or current value output from AC/DC converter 14 and/or power storage device 12. When each of these current values is measured, it is necessary to measure a current value at a point on DC bus 15 between branch node (Nb) of power storage device 12 and DC load 1L or between branch node (Nb) and power storage device 12.

Controller 16 transmits first and second data measured in the above manner to central monitoring system 2 over the network, as the monitoring data of power source systems 10, at regular intervals (for example, once in ten minutes).

When a power failure occurs in system power source 5, switching section 13 switches its connection target from system power source 5 to diesel power generation device 11. This switching operation may be performed in a hardware manner or under software control of controller 16. After the power failure occurs, diesel power generation device 11 waits for an activation instruction from controller 16. Battery manager 121 turns on switch 122. By receiving a power failure sensing signal from a power failure sensor or controller 16, battery manager 121 recognizes the occurrence of the power failure.

A discharge start voltage across power storage modules m1 to mn is set to be lower than the reference voltage on DC bus 15 by a preset value. After switch 122 is turned on, when the voltage on DC bus 15 becomes lower than the voltage across power storage modules m1 to mn, power storage device 12 starts discharging electric power to DC bus 15. After the discharging operation starts, when a remaining capacity of power storage modules m1 to mn reaches their lower limit, battery manager 121 transmits a discharge termination notification to controller 16. The lower limit of the remaining capacity refers to a value set to protect a battery by suppressing overdischarge and may be specified by a voltage or the SOC. A lifetime of a storage battery tends to be shortened as a depth of discharge (DOD) is used deeply.

In response to reception of the discharge termination notification from battery manager 121, controller 16 transmits an operation instruction to diesel power generation device 11. Alternatively, battery manager 121 may be configured to directly transmit the operation instruction to diesel power generation device 11. Diesel power generation device 11 may have an operation determination function and be configured to perform control in relation to an operational state. When diesel power generation device 11 starts generating electric power in response to reception of the operation instruction, the voltage on DC bus 15 starts increasing. When the voltage on DC bus 15 exceeds the voltage across power storage modules m1 to mn, charging of the electric power from DC bus 15 to power storage device 12 starts. After the charging operation starts, when the remaining capacity of power storage modules m1 to mn reaches an upper limit, battery manager 121 transmits a charge termination notification to controller 16. The upper limit of the remaining capacity refers to a value set to protect a battery by suppressing overcharge and may be specified by a voltage or the SOC.

In response to reception of the charge termination notification from battery manager 121, controller 16 transmits a stop instruction to diesel power generation device 11. Alternatively, battery manager 121 may be configured to directly transmit the stop instruction to diesel power generation device 11. Diesel power generation device 11 may have the operation determination function and be configured to perform control in relation to an operational state. When diesel power generation device 11 stops generating the electric power in response to the reception of the stop instruction, the voltage on DC bus 15 starts decreasing. When the voltage on DC bus 15 decreases to below the voltage across power storage modules m1 to mn, power storage device 12 resumes discharging the electric power. The above control operation is repeated until system power source 5 recovers.

As described above, when a power failure occurs in system power source 5, power source system 10 operates both power storage device 12 and diesel power generation device 11 to supply a backup power source to DC load 1L until system power source 5 recovers. A basic backup operation is performed such that power storage device 12 is charged in advance and sensing of a power failure triggers power storage device 12 to supply the electric power. When the electric power supplied from power storage device 12 decreases, diesel power generation device 11 is activated.

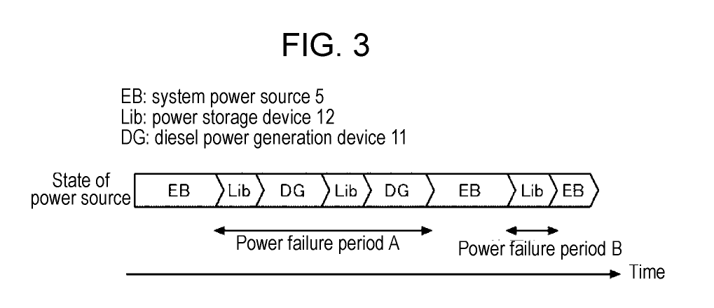

FIG. 3 illustrates an example of a time transition of a state of a power source in certain power source system 10. When a power failure occurs in system power source 5, a power source that supplies electric power to DC load 1L is changed from system power source 5 (denoted by EB in FIG. 3) to power storage device 12 (denoted by Lib in FIG. 3). When this power failure lasts for a long period (see power failure period A), the power source that supplies the electric power to DC load 1L is alternately switched between power storage device 12 and diesel power generation device 11 (denoted by DG in FIG. 3). When the power failure lasts for only a short period (see power failure period B), power storage device 12 operates alone to serve as the power source that supplies the electric power to DC load 1L.

If the power source in power source system 10 is not controlled in accordance with stability of system power source 5, diesel power generation device 11 may operate over an unexpectedly long period, thereby causing a problem that diesel power generation device 11 consumes excessive amounts of fuel. Running out of the fuel in diesel power generation device 11 results in shutdown of overall communication facility 1. In addition, if diesel power generation device 11 operates over a long time, fuel and labor costs may increase. A reason why the labor cost increases is that an engineer needs to manually supply and carry the fuel.

Behaviors of all devices in power source system 10 provided in a site where communication facility 1 is installed are not necessarily measured. For example, if diesel power generation device 11 is configured to automatically start up and stop in accordance with a power supply state at the site, no data on start and stop times of diesel power generation device 11 is left. For example, if only data regarding an AC system and an electrical system of DC bus 15 is measured, it is difficult to identify from which system power source 5 or diesel power generation device 11 the data on the AC system has been output.

If an enormous number of sites are present, it is difficult to unify specifications of power source systems 10 at all the sites and also difficult to unify machines used as diesel power generation devices 11 and power storage devices 12. When constructing power source systems 10, workers sometimes fail to perfectly install and set apparatuses in consideration of differences among the apparatuses and installation environments.

Many power source systems 10 in developing countries disable present settings and environment to be checked from the outside. Therefore, it is difficult to verify a fuel consumption. Furthermore, power failures may occur frequently, and power source infrastructure may be complicated. Electric power systems may fail to sufficiently and reliably collaborate with one another. Different patterns of power failures may occur in different sites. Power failures may occur at different times per month, and no exact data may be left. Materials and fuels may be at a higher risk of being stolen in developing countries than in developed countries.

Under the above situation, attempts to reduce fuel costs have been made. However, it is difficult to verify results of these attempts, which may reduce motivations for continuing such activities. Hereinafter, a description will be given of a mechanism for using power source monitoring data processing device 3 to efficiently and continuously attempt to reduce fuel costs.

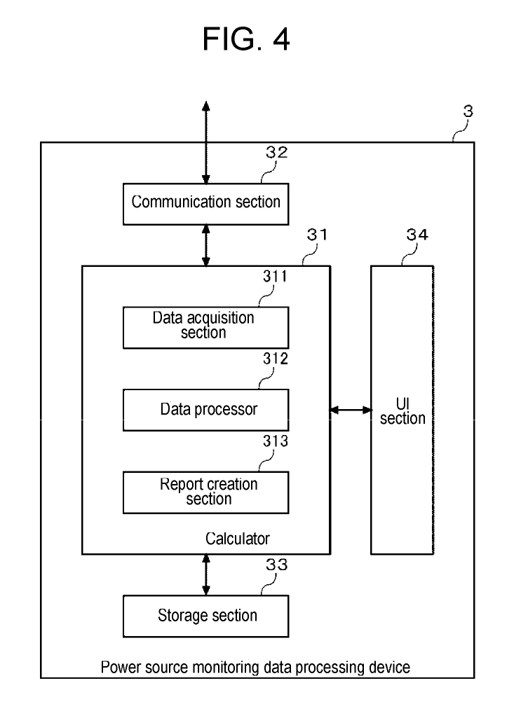

FIG. 4 illustrates an example of a configuration of power source monitoring data processing device 3 according to the exemplary embodiment of the present invention. Power source monitoring data processing device 3 includes calculator 31, communication section 32, storage section 33, and user interface (UI) section 34. Calculator 31 includes data acquisition section 311, data processor 312, and report creation section 313.

A configuration of calculator 31 is implemented by cooperation of hardware and software resources. The hardware resource may be a central processing unit (CPU), read only memory (ROM), random access memory (RAM), or any other large scale integrated circuit (LSI). The software resource may be a program, such as an operating system (OS) or an application. Communication section 32 performs a communication process in conformity with a predetermined communication protocol. A configuration of communication section 32 may be implemented by either the cooperation of the hardware and software resources or the hardware resource alone. Storage section 33 is provided with a non-volatile memory, such as a hard disk device (HDD) or a silicon disk drive (SDD). UI section 34 is provided with input devices such as a keyboard, a mouse, a microphone, and a touch panel, and output devices such as a display, speakers, and a printer.

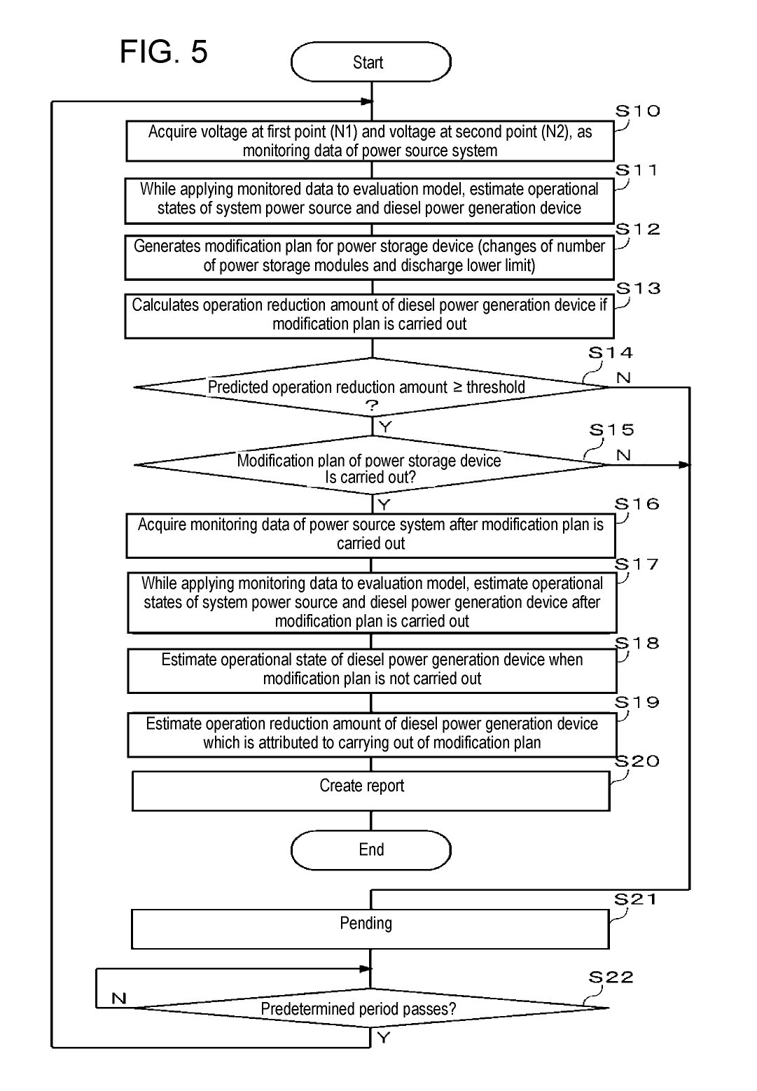

FIG. 5 is a flowchart of an example of an operation of power source monitoring data processing device 3 according to the exemplary embodiment of the present invention. A precondition in this operation example is that it is impossible to acquire direct data indicating operational states of system power source 5 and diesel power generation device 11. In other words, the precondition is that it is impossible to acquire exact data on periods in which system power source 5 is normal, in which a power failure lasts in system power source 5, in which diesel power generation device 11 generates the electric power, and in which diesel power generation device 11 stops its operation.

At step S10, data acquisition section 311 acquires the first and second data, as monitoring data (performance data) of power source system 10 being targeted. The monitoring data is preferably collected continuously over a preset period. At step S11, data processor 312 applies the first and second data to a predetermined evaluation model, thereby estimating the operational states of system power source 5 and diesel power generation device 11. The evaluation model may be created based on behaviors of the first and second data for many power source systems 10. In general, AC waveforms of system power source 5 and diesel power generation device 11 tend to fluctuate with different stabilities. In short, data processor 312 can estimate the operational state of diesel power generation device 11, based on differences, for example, in stability and time transition of stability between varying AC waveforms of the first and second data.

Data processor 312 can also estimate the operational state of power storage device 12, based on the first and second data. When the first data is substantially zero and the second data falls within a normal range of a current/voltage output to DC load 1L, data processor 312 estimates that power storage device 12 is in a discharging state. When the first data falls within the normal range of the current/voltage output to DC load 1L, data processor 312 estimates that power storage device 12 is in a stop/charging state.

At step S12, data processor 312 generates a modification plan for power storage device 12, based on the stability of system power source 5 and the operational states of diesel power generation device 11 and power storage device 12 in power source system 10 being targeted. The modification plan for power storage device 12 refers to a modification plan intended to shorten an operational time of diesel power generation device 11, and is generated by entry of the above parameters in a predetermined modification plan generation model. The modification plan generation model may be created based on engineers' knowledge and/or learning data on a history of modifications of many power source systems 10.

The modification plan generation model exemplified below includes: changing a system configuration of power storage device 12; and/or changing settings for power storage device 12. Used as specific modification items are the number of power storage modules and a discharge lower limit of the power storage modules. In order to shorten an operational time of diesel power generation device 11, it is necessary to prolong a discharging time of power storage device 12. A method to achieve this purpose includes: increasing the power storage capacity; and deepen the discharge depth.

The power storage capacity may be increased by an increase in the number of power storage modules interconnected in parallel. The discharge depth may be deepened by lowering the discharge lower limit. The discharge lower limit is usually set to a recommended value described in a specification sheet provided by a battery manufacturer, when power storage device 12 is installed. Therefore, power storage device 12 can be used in a deeper region without danger, depending on a usage environment (for example, an ambient temperature) of power storage device 12. Regardless of whether the modification plan is present, battery manager 121 preferably changes the discharge lower limit in consideration of degradation of a battery.

At step S13, data processor 312 calculates a predicted value of an operation reduction amount of diesel power generation device 11 if the above modification plan is carried out, based on past operational state data of system power source 5 in power source system 10 being targeted. The operation reduction amount may be calculated from at least one of a shortened time, a fuel reduction amount, and a fuel reduction cost. When the calculation is made from the fuel reduction cost, a net reduction cost is preferably used. More specifically, a value obtained by subtracting an additional cost (for example, a cost of installing additional power storage modules) involved in carrying out the modification plan for power storage device 12 from a fuel reduction cost of diesel power generation device 11 may be used.

At step S14, data processor 312 compares the calculated predicted value of the operation reduction amount and a predetermined threshold. Predetermined thresholds may be specified for respective additional power storage modules. When the predicted value of the operation reduction amount is less than the predetermined threshold (N at step S14), at step S21, suggestion or carrying out of the above modification plan is suspended. When the predicted value of the operation reduction amount is equal to or more than the predetermined threshold (Y at step S14), the above modification plan is suggested or reported to an administrator of power source system 10. The suggestion or report of the modification plan may be transmitted from communication section 32 to an administrator's terminal device over the network. Alternatively, the suggestion or report is directly submitted by a service person to the administrator.

The case where the predicted value of the operation reduction amount is less than the predetermined threshold refers to a case where carrying out the modification plan is estimated not to greatly improve fuel reduction. The degree of the improvement mainly depends on a pattern of a power failure in system power source 5 within power source system 10 and environment conditions of a place where power source system 10 is installed. Even if additional power storage modules are further installed, some patterns of a power failure in system power source 5 may hinder an improvement in the operation reduction amount of diesel power generation device 11. However, the pattern of the power failure in system power source 5 and/or the environment conditions may change with time. Therefore, even when the fuel reduction is estimated not to be greatly improved, modification of the system configuration and/or settings of power storage device 12 might contribute to a great improvement in the fuel reduction.

When the above modification plan is carried out (Y at step S15), at step S16, data acquisition section 311 acquires first and second data, as monitoring data of power source system 10 after the modification plan is carried out. By monitoring a detection value of a sensor (not illustrated) disposed in power storage device 12, it is possible to sense whether the system configuration and/or settings of power storage device 12 are actually modified in accordance with the modification plan. Alternatively, the modification of the system configuration and/or settings may be sensed in response to reception of a modification completion notification that an operator has entered in a terminal device, over the network.

At step S17, data processor 312 applies the first and second data acquired after the modification plan is carried out to the above evaluation model, thereby estimating the operational states (performance data) of system power source 5 and diesel power generation device 11. At step S18, based on the estimated operational state (performance data) of system power source 5, data processor 312 estimates an operational state (estimated data) of diesel power generation device 11 when the modification plan is not carried out.

At step S19, data processor 312 compares the operational state (performance data) of diesel power generation device 11 acquired after the modification plan is carried out and the operational state (estimated data) of diesel power generation device 11 when the modification plan is not carried out. In this way, data processor 312 estimates an operation reduction amount of diesel power generation device 11 which is attributed to the carrying out of the modification plan. For example, data processor 312 may estimate the operation reduction amount by calculating a difference between operational times of diesel power generation device 11. At step S20, report creation section 313 creates a fuel reduction performance evaluation report that contains the estimated operation reduction amount of diesel power generation device 11. Then, communication section 32 transmits the created fuel reduction performance evaluation report to the terminal device of the administrator for power source system 10 via the network. Alternatively, the fuel reduction performance evaluation report may be printed out by a printer, which then mailed or handed to the administrator.

The processes at steps S10 to S20 may be individually performed in power source systems 10 at regular intervals (for example, once a month) or as appropriate. For example, if system power source 5 is being reconstructed for improvement, the above processes may be performed immediately after the reconstruction is completed. After the modification plan is carried out, power source system 10 is regarded as a modified site. Power source monitoring data processing device 3 retains the modified system configuration and/or settings and continues to collect data.

After the modification plan is suggested or reported to the administrator at step S15, if the modification plan is not carried out (N at step S15), power source system 10 is regarded as a pending site at step S21. When a predetermined period (for example three months) passes since power source system 10 is regarded as the pending site (step S21) (Y at step S22), power source monitoring data processing device 3 returns this processing to step S10. Then, power source monitoring data processing device 3 regenerates a modification plan for power storage device 12 at steps S10 to S13. An interval period until a modification plan for the pending site is regenerated is set to be longer than an interval period until a modification plan for the modified site is regenerated. The pending site is a site that has limited possibility for improvement or whose administrator does not has a high motivation for improvement. By decreasing a frequency at which a modification plan for the pending site is generated, it is possible to lighten a process load involved in generating the modification plan.

According to the foregoing exemplary embodiment, each power source system 10, which has both diesel power generation device 11 and power storage device 12, enables efficient and continuous power source backup setting such that the amount of fuel consumed in diesel power generation device 11 is reduced. More specifically, power source monitoring data processing device 3 collects data on each power source system 10 which is generated before and after a modification plan is carried out and then estimates operational states of diesel power generation device 11, power storage device 12, and system power source 5. After that, power source monitoring data processing device 3 generates the modification plan based on the estimated value and creates a fuel reduction performance evaluation report on the carrying out of the modification plan.

Power source monitoring data processing device 3 can not only set initial system configuration and design items but also achieve an efficient and continuous operation of facilities in power source systems 10. In addition, power source monitoring data processing device 3 enables modifications of the system configurations and/or settings of power storage devices 12 in consideration of varying stabilities of system power sources 5 over a long period. Furthermore, power source monitoring data processing device 3 concurrently enables verification of an effect of the modified system configurations and/or settings. Consequently, it is possible to appropriately evaluate an effect of the modification.

The above site control enables an efficient and continuous operation of power source system 10. In addition, by using operational data and performance evaluations in combination, it is possible to quantitatively verify an effect of an improvement suggestion service for fuel reduction. However, this improvement suggestion service is not highly required for a power source system that includes a solar photovoltaic system and a power storage device. A reason is that a cost of generating electric power (a cost of fossil fuel) is constant regardless of whether a system configuration and/or settings of the power storage device are modified.

The present invention has been described based on the exemplary embodiment. It is to be understood to a person with ordinary skill in the art that the exemplary embodiment is an example, and various modifications of each of component elements and combinations of each treatment process may be made and the modifications are included within the scope of the present invention.

In the foregoing exemplary embodiment, exact operational data of system power source 5 and diesel power generation device 11 is supposed to be unobtainable. At a site where exact operational data of system power source 5 and/or diesel power generation device 11 is obtainable, it is unnecessary to estimate an operational state(s) of system power source 5 and/or diesel power generation device 11. In this case, the operational data obtained from a measurement may be used directly. At a site where operational or state data of power storage device 12 is obtainable, it is possible to generate a modification plan for a system configuration and/or settings with higher accuracy in consideration of degradation and environment conditions of power storage device 12.

When generating the modification plan at step S12 in the flowchart of FIG. 5, data processor 312 may calculate a comprehensive cost reduction effect in consideration of a long lifetime of a storage battery. In this case, data processor 312 may consider a forecast about a lifetime of a power storage capacity, based on operational data of the storage battery. Furthermore, power source monitoring data processing device 3 may be configured to receive external data, as auxiliary determination information to be used when a modification plan is generated. Power source monitoring data processing device 3 may output, to the outside, as auxiliary information, a summed or estimated value of data that can be used as an evidence for generating a modification plan. Providing an input/output interface in this manner can reflect a decision of a human, such as an engineer in charge, thereby successfully generating a modification plan with higher accuracy. Moreover, it is possible to make an amendment based on a skilled engineer's experimental rule.

Data processor 312 generates statistical data by continuously collecting and summarizing performance data of power source system 10. This statistical data can be used to sense a sign of any abnormality that may occur in overall equipment and/or each individual facility in power source system 10. In addition, data processor 312 may amend a system configuration and/or settings of power storage device 12, based on the sensing result, so that the system configuration and/or settings conform to an aged state and other factors.

Instead of or in addition to switch 122, a DC/DC converter is connected between DC bus 15 and power storage modules m1 to mn. This configuration enables battery manager 121 to actively control a charging current/voltage and a discharging current/voltage. In short, battery manager 121 can adjust a charging/discharging pattern. In this case, a modified charging/discharging pattern may be added to modified setting items for power storage devices 12.

In the foregoing exemplary embodiment, report creation section 313 is configured to create the fuel reduction performance evaluation report that contains an estimated operation reduction amount of diesel power generation device 11. Hereinafter, a specific example of the fuel reduction performance evaluation report will be described.

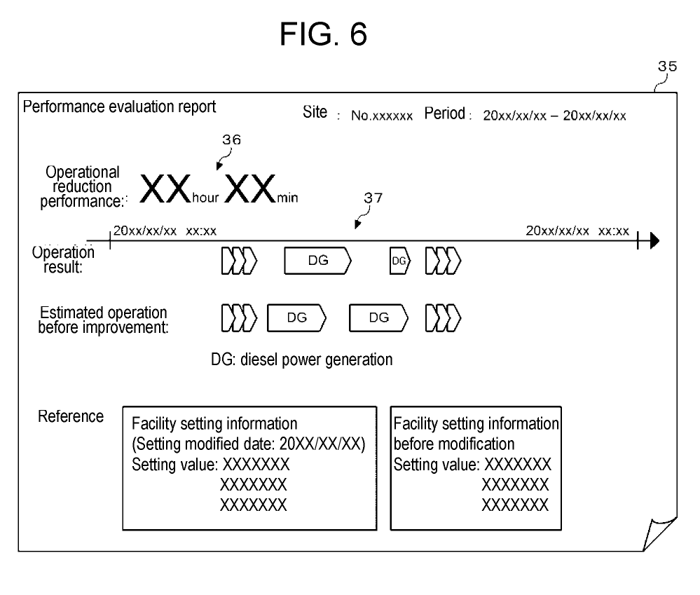

FIG. 6 illustrates an example of a format of the fuel reduction performance evaluation report. In performance evaluation report 35 illustrated in FIG. 6, reduction amount (time) 36 of an operational time of diesel power generation device 11 is described as a value of a fuel reduction performance over a predetermined period. As the value of the fuel reduction performance over the period, a reduction amount (money amount) of fuel calculated from an operational efficiency and operational time of diesel power generation device 11 and a unit price of fuel used over this period may be described. Alternatively, only a reduction amount (money amount) of fuel may be described.

In performance evaluation report 35 illustrated in FIG. 6, a time transition performance of an operational state of diesel power generation device 11 over the period is described. In the example of FIG. 6, the time transition performance of the operational state is indicated by a time transition graph. If the time transition graph cannot contain the entire period, the time transition graph may indicate only a portion of this period.

The above time transition graph corresponds to a graph that visualizes a timing of supply from DG in FIG. 3, based on the performance data. Since exact detection information on EB/Lib/DG is supposed to be unobtainable, this time transition graph visualizes an estimated amount based on the performance data. This estimated amount does not represent “an operational state (estimated data) of diesel power generation device 11 when the modification plan is not carried out”, and is a time transition performance of the operational state estimated from the performance data.

In addition to the timing of the power supply from DG, the graph may visualize timing(s) of power supply from EB and/or Lib. In this case, a formation of the graph is identical to the format of the graph indicating the time transitions of the states of the power sources in FIG. 3. The graph may also visualize a power failure period estimated from the performance data. In FIG. 3, the arrows each indicating the power failure period are added to the time transition graph indicating the states of the power sources in FIG. 3.

A time transition graph that visualizes an operational state (estimated data) where diesel power generation device 11 operates when the modification plan is not carried out may be used. A format of this time transition graph of FIG. 3 corresponds to a format in which the time transition graphs indicating the states of power sources before and after the modification plan is carried out are described vertically. The time transition graph in this format helps understanding of the degree to which the operation of DG improves. In the time transition graph corresponding to the case where the modification plan is not carried out, not only the timing of the power supply from DG but also the timing(s) of the power supply from EB and/or Lib may be described. In addition, arrows indicating a power failure period may also be described.

Optionally, present setting information and/or setting information (past setting information) that indicates a case where the modification plan is not carried out may be described as reference information. Not all site administrators always memorize present and/or past setting state(s). Therefore, the present and/or past setting state(s) is (are) preferably described.

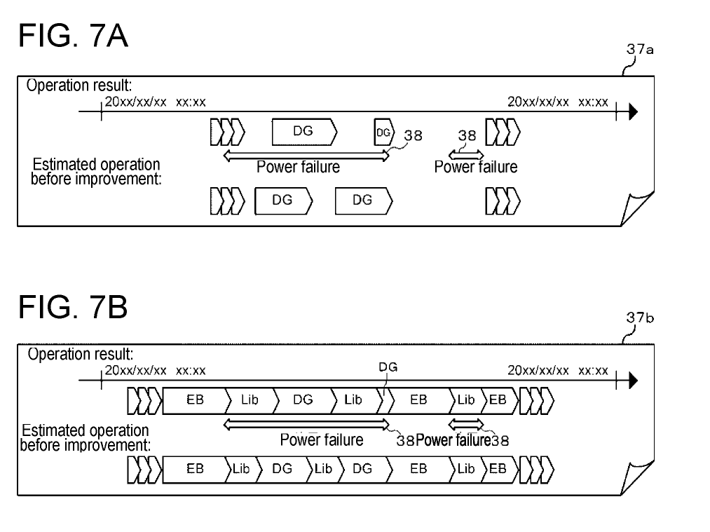

FIGS. 7(a) and 7(b) each illustrate a modification of graph area 37 of FIG. 6 in which an operation result and an estimated operation before improvement are shown. Graph area 37a in FIG. 7(a) is equivalent to graph area 37 in FIG. 6 to which arrows 38 each indicating a power failure period are added. Graph area 37b in FIG. 7(b) is equivalent to a format example in which arrows 38 each indicating a power failure period are added and the timings of power supply from EB and/or Lib are described.

The exemplary embodiment may be specified by the items described below.

### [Item 1]

Power source monitoring data processing device (3) including: data acquisition section (311) that acquires first data and second data as monitoring data of power source system (10), power source system (10) including switching section (13) that selectively outputs alternating current (AC) power supplied from system power source (5) or internal combustion power generation device (11), alternating current/direct current (AC/DC) converter (14) that converts the AC power output from switching section (13) into direct current (DC) power and outputs the DC power to DC load (1L), and power storage device (12) connected to DC bus (15) between AC/DC converter (14) and DC load (1L), the first data containing an output voltage and/or an output current of switching section (13), the second data containing an output voltage and/or an output current of power source system (10); and data processor (312) that estimates an operational state of internal combustion power generation device (11), based on the first data and the second data acquired by data acquisition section (311) and that generates a modification plan for a system configuration and/or a discharge lower limit of power storage device (12) to shorten an operational time of internal combustion power generation device (11).

Power source monitoring data processing device (3) configured above achieves a continuous and efficient operation of power source system (10) in which power storage device (12) and internal combustion power generation device (11) collaborate with each other.

### [Item 2]

Power source monitoring data processing device (3) according to Item 1, in which data processor (312) estimates the operational state of internal combustion power generation device (11), based on variations in the first data and the second data.

The word “variation” refers to a variation based on at least one of physical quantity variables, such as “stability” and “time transition of stability”.

Power source monitoring data processing device (3) configured above can generate the modification plan for power storage device (12) even if unable to directly acquire operational data of internal combustion power generation device (11).

### [Item 3]

Power source monitoring data processing device (3) according to Item 1 or 2, in which data acquisition section (311) acquires the first data and the second data of power source system (10) after the modification plan for power storage device (12) is carried out, and data processor (312) estimates the operational state of internal combustion power generation device (11) and an operational state of system power source (5) after the modification, based on the first data and the second data of power source system (10) after the modification, and estimates the operational state of internal combustion power generation device (11) when the modification plan is not carried out, based on the operational state of system power source (5), and compares the operational states of internal combustion power generation device (11) when the modification plan is not carried out and after the modification plan is carried out, to estimate an operation reduction amount of internal combustion power generation device (11) caused by carrying out of the modification plan.

Power source monitoring data processing device (3) configured above can quantitatively evaluate a fuel reduction effect produced by carrying out of the modification plan.

### [Item 4]

Power source monitoring data processing device (3) according to Item 3, in which data processor (312) determines whether to suspend regeneration of the modification plan, based on the operation reduction amount of internal combustion power generation device (11).

Power source monitoring data processing device (3) configured above can decrease a number of modification plans to be generated, thereby lightening a process load.

### [Item 5]

Power source monitoring data processing device (3) according to Item 4, in which when the operation reduction amount is smaller than a predetermined threshold or when the modification plan is not carried out over a preset period, data processor (312) suspends the regeneration of the modification plan.

Power source monitoring data processing device (3) configured above can efficiently utilize a resource of power source monitoring data processing device (3) by suspending the regeneration of the modification plan for power source system (10) that is estimated not to produce a great improvement effect.

### [Item 6]

Power source monitoring data processing device (3) according to any one of Items 1 to 5, in which a modification of the system configuration of power storage device (12) includes increasing or decreasing a number of power storage modules (m1 to mn) that constitute power storage device (12), and data processor (312) generates the modification plan, based on an increased cost involved in carrying out the modification plan for power storage device (12) and a decreased cost of a fossil fuel involved in shortening the operational time of internal combustion power generation device (11).

Power source monitoring data processing device (3) configured above calculates net cost performance when carrying out the modification plan.

### [Item 7]

Power source monitoring data processing device (3) according to any one of Items 1 to 6, in which data processor (312) detects an abnormality of power source system (10), based on the first data and the second data of power source system (10) acquired after the modification plan for power storage device (12) is carried out.

Power source monitoring data processing device (3) configured above can efficiently utilize collected data for not only fuel reduction but also other purposes.

### [Item 8]

A power source monitoring data processing method including: acquiring first data and second data as monitoring data of power source system (10), power source system (10) including switching section (13) that selectively outputs alternating current (AC) power supplied from system power source (5) or internal combustion power generation device (11), alternating current/direct current (AC/DC) converter (14) that converts the AC power output from switching section (13) into direct current (DC) power and outputs the DC power to DC load (1L), and power storage device (12) connected to DC bus (15) between AC/DC converter (14) and DC load (1L), the first data containing an output voltage and/or an output current of switching section (13), the second data containing an output voltage and/or an output current of power source system (10); and estimating an operational state of internal combustion power generation device (11), based on the first data and the second data, and generating a modification plan for a system configuration and/or a discharge lower limit of power storage device (12) to shorten an operational time of internal combustion power generation device (11).

Power source monitoring data processing device (3) configured above achieves a continuous and efficient operation of power source system (10) in which power storage device (12) and internal combustion power generation device (11) collaborate with each other.

### [Item 9]

A power source monitoring data processing program that causes a computer to perform functions including; acquiring first data and second data as monitoring data of power source system (10), power source system (10) including switching section (13) that selectively outputs alternating current (AC) power supplied from system power source (5) or internal combustion power generation device (11), alternating current/direct current (AC/DC) converter (14) that converts the AC power output from switching section (13) into direct current (DC) power and outputs the DC power to DC load (1L), and power storage device (12) connected to DC bus (15) between AC/DC converter (14) and DC load (1L), the first data containing an output voltage and/or an output current of switching section (13), the second data containing an output voltage and/or an output current of power source system (10); and estimating an operational state of internal combustion power generation device (11), based on the first data and the second data, and generating a modification plan for a system configuration and/or a discharge lower limit of power storage device (12) to shorten an operational time of internal combustion power generation device (11).

Power source monitoring data processing device (3) configured above achieves a continuous and efficient operation of power source system (10) in which power storage device (12) and internal combustion power generation device (11) collaborate with each other. The computer program may be stored in a non-transitory computer readable medium.

### REFERENCE MARKS IN THE DRAWINGS

1: communication facility
1L: DC load
2: central monitoring system
3: power source monitoring data processing device
31: calculator
311: data acquisition section
312: data processor
313: report creation section
32: communication section
33: storage section
34: UI section
5: system power source
10: power source system
11: diesel power generation device
12: power storage device
m1, m2, mn: power storage module
121: battery manager
122: switch
13: switching section
14: AC/DC converter
15: DC bus
16: controller

1. A power source monitoring data processing device comprising:
a data acquisition section that acquires first data and second data as monitoring data of a power source system, the power source system including a switching section that selectively outputs alternating current (AC) power supplied from a system power source or an internal combustion power generation device, an alternating current/direct current (AC/DC) converter that converts the AC power output from the switching section into direct current (DC) power and outputs the DC power to a DC load, and a power storage device connected to a DC bus between the AC/DC converter and the DC load, the first data containing an output voltage and/or an output current of the switching section, the second data containing an output voltage and/or an output current of the power source system; and
a data processor that estimates an operational state of the internal combustion power generation device, based on the first data and the second data acquired by the data acquisition section and that generates a modification plan for a system configuration and/or a discharge lower limit of the power storage device to shorten an operational time of the internal combustion power generation device.

2. The power source monitoring data processing device according to claim 1, wherein the data processor estimates the operational state of the internal combustion power generation device, based on variations in the first data and the second data.

3. The power source monitoring data processing device according to claim 1, wherein the data acquisition section acquires the first data and the second data of the power source system after the modification plan for the power storage device is carried out, and
the data processor
estimates the operational state of the internal combustion power generation device and an operational state of the system power source after the modification, based on the first data and the second data of the power source system after the modification, and
estimates the operational state of the internal combustion power generation device when the modification plan is not carried out, based on the operational state of the system power source, and compares the operational states of the internal combustion power generation device when the modification plan is not carried out and after the modification plan is carried out, to estimate an operation reduction amount of the internal combustion power generation device caused by carrying out of the modification plan.

4. The power source monitoring data processing device according to claim 3, wherein the data processor determines whether to suspend regeneration of the modification plan, based on the operation reduction amount of the internal combustion power generation device.

5. The power source monitoring data processing device according to claim 4, wherein when the operation reduction amount is smaller than a predetermined threshold or when the modification plan is not carried out over a preset period, the data processor suspends the regeneration of the modification plan.

6. The power source monitoring data processing device according to claim 1, wherein a modification of the system configuration of the power storage device includes increasing or decreasing a number of power storage modules that constitute the power storage device, and
the data processor generates the modification plan, based on an increased cost involved in carrying out the modification plan for the power storage device and a decreased cost of a fossil fuel involved in shortening the operational time of the internal combustion power generation device.

7. The power source monitoring data processing device according to claim 1, wherein the data processor detects an abnormality of the power source system, based on the first data and the second data of the power source system acquired after the modification plan for the power storage device is carried out.

8. A power source monitoring data processing method comprising: acquiring first data and second data as monitoring data of a power source system, the power source system including a switching section that selectively outputs alternating current (AC) power supplied from a system power source or an internal combustion power generation device, an alternating current/direct current (AC/DC) converter that converts the AC power output from the switching section into direct current (DC) power and outputs the DC power to a DC load, and a power storage device connected to a DC bus between the AC/DC converter and the DC load, the first data containing an output voltage and/or an output current of the switching section, the second data containing an output voltage and/or an output current of the power source system; and
estimating an operational state of the internal combustion power generation device, based on the first data and the second data, and generating a modification plan for a system configuration and/or a discharge lower limit of the power storage device to shorten an operational time of the internal combustion power generation device.

9. A non-transitory computer readable medium in which a power source monitoring data processing program is stored that causes a computer to perform functions comprising: acquiring first data and second data as monitoring data of a power source system, the power source system including a switching section that selectively outputs alternating current (AC) power supplied from a system power source or an internal combustion power generation device, an alternating current/direct current (AC/DC) converter that converts the AC power output from the switching section into direct current (DC) power and outputs the DC power to a DC load, and a power storage device connected to a DC bus between the AC/DC converter and the DC load, the first data containing an output voltage and/or an output current of the switching section, the second data containing an output voltage and/or an output current of the power source system; and
estimating an operational state of the internal combustion power generation device, based on the first data and the second data, and generating a modification plan for a system configuration and/or a discharge lower limit of the power storage device to shorten an operational time of the internal combustion power generation device.
